(19) United States
(12) Patent Application Publication
(10) Pub. No.: US 2004/0040656 A1
(43) Pub. Date: Mar. 4, 2004

(54) Method and apparatus for CMP retaining ring

(76) Inventors: Raymond J. Hengel JR., Round Rock, TX (US); George J. Frank JR., Austin, TX (US)

Correspondence Address: Rick B. Yeager, 10805 Mellow Lane, Austin, TX, 78759, US

(21) Appl. No.: 10/651,174

(22) Filed: Aug. 28, 2003

Related U.S. Application Data
(60) Provisional application No. 60/406,945, filed on Aug. 28, 2002.

(51) Int. Cl. H01L 21/306; C23F 1/00; B32B 31/00; C09J 1/00

(52) U.S. Cl. 156/345.14; 156/281; 156/295

(57) ABSTRACT

A two piece, metal and plastic, retaining ring used for chemical mechanical polishing of semiconductor substrates. In one embodiment, the plastic is selected from polyphenylene sulfide (PPS), polyethylene terephthalate, polyetheretherketone, polybutylene terephthalate, Ertalyte TX, PEEK, Torlon, Delrin, PET, Vespel, or Duratrol, and the plastic is assembled to a stainless steel ring with a urethane adhesive at room temperature. In another embodiment, the plastic is assembled to the metal portion with an acrylic adhesive at room temperature.

### CROSS-REFERENCE TO RELATED APPLICATIONS

This application is related to and claims the benefit of U.S. Provisional Patent Application No. 60/406,945 filed Aug. 28, 2002.

### FIELD OF INVENTION

This invention relates to a two part retaining ring typically used in chemical mechanical polishing operations.

### BACKGROUND

The present invention relates to a retaining ring used in the process of chemical mechanical polishing of semiconductor substrates. The substrate is typically a thin disc of semiconductor material with deposited alternate layers of conductive, semiconductive, and insulating materials. The layers are etched to produce electrical circuitry on the surface of the substrate. A typical substrate has a series of layers deposited and circuitry etched. The deposition and etching process after many layers produces a non flat top surface. This unflatness prevents accurate deposition of subsequent layers. Planarization of the substrate is periodically required to maintain an acceptable substrate surface. Chemical mechanical polishing of the topmost surface of the substrate produces a sufficiently flat surface to allow accurate subsequent deposition and etching of layers. This method of planarization is affected on a substrate by use of a polishing machine. Among the many subassemblies of this machine is the polishing head or carrier head. The polishing head contains among its components a retaining ring. This ring positions and retains the substrate allowing the other components of the head to exert pressure against the substrate which in turn moves relative to a polishing pad, usually wetted by a polishing medium or slurry.

The retaining ring is typically formed from two pieces. The first, or upper, piece is usually of a metal material such as stainless steel, aluminum, or molybdenum, but may be other materials. The second, or lower, piece is of a plastic material such as polyphenylene sulfide (PPS), polyethylene terephthalate, polyetheretherketone, polybutylene terephthalate, Ertalyte TX, PEEK, Torlon, Delrin, PET, Vespel, or Duratrol.

U.S. Pat. No. 6,251,215 to Zuniga describes a two part chemical mechanical polishing (CMP) retaining ring where the first part is polyphenylene sulfide (PPS) and the second part is metal and the parts are joined by an epoxy adhesive.

Semiconductor fabrication facilities are increasing the temperature of the CMP process, and these temperatures can exceed the effective temperature range of epoxy adhesives. There is a need for CMP retaining rings which can withstand higher operating temperatures.

Applicant believes that prior art epoxy adhesive retaining rings typically use an oven curing operation. There is need to provide a retaining ring room temperature manufacturing process which reduces the retaining ring cost.

### SUMMARY

The invention is directed toward an apparatus and method of fastening together two parts of a retaining ring used in the chemical mechanical polishing process of a semiconductor substrate. The first, or upper, part is typically a metal material such as stainless steel, aluminum, or molybdenum. The second, or lower, part is of a plastic material such as PPS. In one embodiment of the current invention, the upper and lower portions are attached with an acrylic adhesive. In another embodiment, the upper and lower portions are attached with a urethane adhesive.

### BRIEF DESCRIPTION OF THE DRAWINGS

These and other objects and advantages of the present invention are set forth below and further made clear by reference to the drawings, wherein:

FIG. 1 is a cross sectional view of the retaining ring.

FIG. 2 is a cross sectional view of a lap shear test device

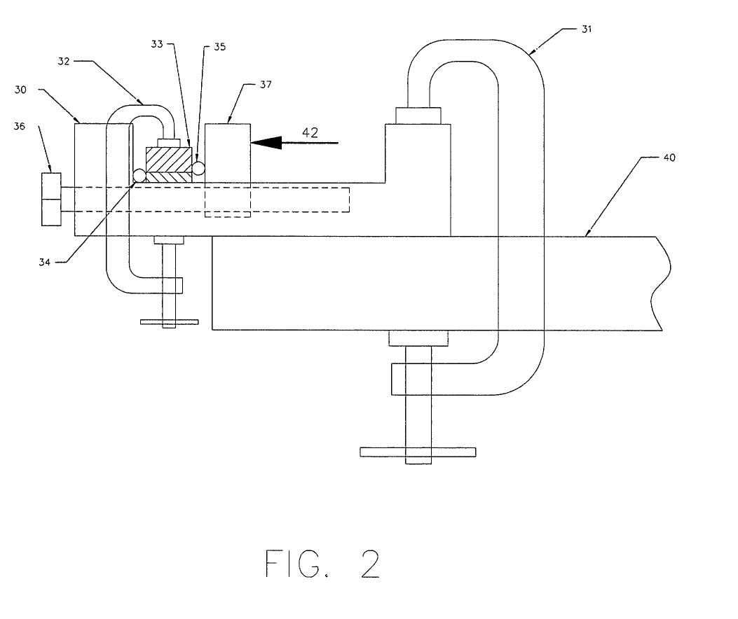

### DETAILED DESCRIPTION OF EMBODIMENT

Retaining ring

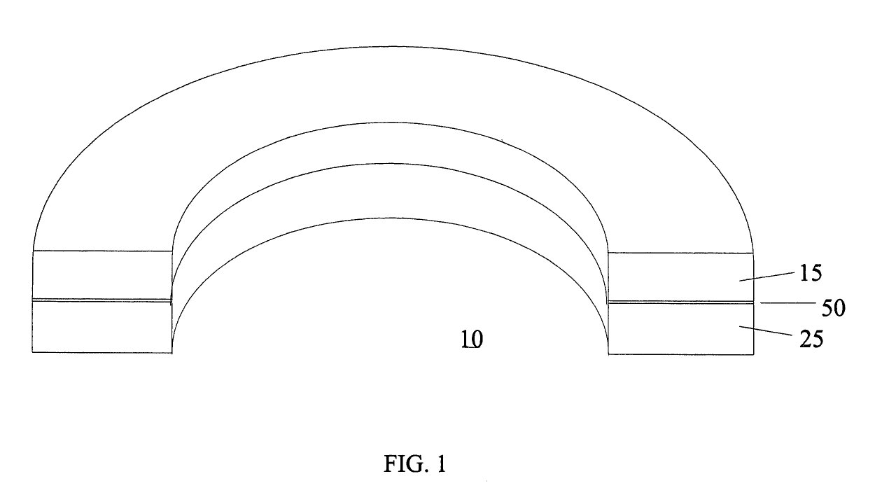

Referring now to FIG. 1 which is a cross sectional view of the retaining ring, the retaining ring 10 is composed of an upper part 15 is typically made of a metal, and the lower part 25 is typically made of plastic. In this embodiment, the upper and lower parts are attached with an adhesive 50 such as an acrylic adhesive or a urethane adhesive.

In this embodiment, the two part ring is fabricated by machining the metal upper portion, machining the lower plastic portion, grit blasting the mating surfaces of the metal and plastic parts with #24 ceramic abrasive to a finish of 150-250 RMS; degreasing the directions on the plastic and metal portions of the test coupon, respectively, to create a shear stress. The magnitude of the stress is observed by measuring the torque on the torque screw 36 as the movable jaw 37 forces the pins to act 42 against the upper and lower portions of the test coupon, thereby testing adhesive sheer strength.

The epoxy adhesives had a shear test of 3000-4286 pounds. The results showed unexpected effectiveness of non-epoxy adhesives as several adhesives outperformed the epoxy adhesive ring samples. The acrylic adhesive Loctite Speedbonder 324 had a shear test of 7286 pounds. The acrylic adhesive Loctite Speedbonder 325 had a shear test of 6429 pounds. The urethane adhesive Loctite Hysol U-05FL had a shear test of 4286 pounds. The urethane and acrylic test results were unexpected, because of the perceived difficulty in finding an adhesive other than epoxy that would bond stainless steel and a plastic while being resistant to the CMP process slurry.

In this test, the best adhesives were found to be Loctite 324 Engineering Adhesive (Technical Data Sheet and Material Safety Data Sheet at http://www.loctite.com/datasheets/msds/32430.html); Loctite 325 Engineering Adhesive (Technical Data Sheet and Material Safety Data Sheet at http://www.loctite.com/datasheets/msds/32530.html); and Durabond 605FL, also called Hysol Product U-05FL; (Technical Data Sheet and Material Safety Data Sheet at http://www.loctite.com/datasheets/msds/29351.html).

Loctite 324 is an acrylic adhesive with the following ingredients: polyurethane methacrylate, hydroxyalkyl methacrylates, a high boiling methacrylate, tert-BUTYL PEROXYBENZOATE, ACRYLIC ACID, and Saccharin. Tests showed a preferred adhesive thickness of about 0.002 inches.

Loctite 325 is an acrylic adhesive with the following ingredients: polyurethane methacrylate resin, polyglycol dimethacrylate, hydroxyalkyl methacrylate, ACRYLIC ACID, tert-BUTYL PEROXYBENZOATE, CUMENE HYDROPEROXIDE, Saccharin, and a substituted silane.

Hysol U-05FL is a Urethane Adhesive Resin from Loctite with the following ingredients: a proprietary polyisocyanate based on methylene bisphenyl isocyanate, METHYLENE BISPHENYL ISOCYANATE, and methylene bisphenyl isocyanate. Tests showed a preferred thickness of about 0.030″. A thinner adhesive layer might be preferable, but is difficult to achieve with a two-part adhesive.

In one embodiment, the first material is stainless steel and the second material is polyphenylene sulfide which includes TechTron® by Quadrant, Ryton® by Chevron-Phillips, and Ensinger by Ensinger Corporation. Other plastics such as polyphenylene sulfide (PPS), polyethylene terephthalate, polyetheretherketone, polybutylene terephthalate, Ertalyte TX, PEEK, Torlon, Delrin, PET, Vespel, or Duratrol.

What is claimed is:

1. A retaining ring for a CMP carrier head the retaining ring, comprising:
a generally annular lower portion having a bottom surface for contacting a polishing pad during polishing and made of a first plastic material selected from the group consisting of polyphenylene sulfide (PPS), polyethylene terephthalate, polyetheretherketone, polybutylene terephthalate, Ertalyte TX, PEEK, Torlon, Delrin, PET, Vespel, or Duratrol; and
a generally annular upper metal portion joined to the lower portion, wherein the the lower portion is affixed to the upper portion by and a urethane adhesive.

2. The ring of claim 1 wherein the urethane adhesive is Hysol U-05FL.

3. A retaining ring for a CMP carrier head the retaining ring, comprising:
a generally annular lower portion having a bottom surface for contacting a polishing pad during polishing and made of a first plastic material selected from the group consisting of polyphenylene sulfide (PPS), polyethylene terephthalate, polyetheretherketone, polybutylene terephthalate, Ertalyte TX, PEEK, Torlon, Delrin, PET, Vespel, or Duratrol.; and
a generally annular upper metal portion joined to the lower portion, wherein the the lower portion is affixed to the upper portion by and an acrylic adhesive.

4. The ring of claim 3 wherein the acrylic adhesive is Loctite Product 324.

5. The ring of claim 3 wherein the acrylic adhesive is Loctite Product 325.

6. A method of fabricating a multilayer retaining ring for a CMP carrier head the method comprising
machining a metal upper portion;
machining a lower plastic portion from a material selected from the group consisting of polyphenylene sulfide (PPS), polyethylene terephthalate, polyetheretherketone, polybutylene terephthalate, Ertalyte TX, PEEK, Torlon, Delrin, PET, Vespel, or Duratrol;
roughening the mating surfaces of the metal and plastic portions;
cleaning the mating surfaces;
applying a urethane adhesive to at least one of the mating surfaces;
pressing the mating surfaces together to forces a portion of the adhesive to flow out of the ring; and
allowing the adhesive to cure at room temperature without special clamping or fixturing.

7. The method of claim 6 wherein the urethane adhesive is Hysol U-05FL.

8. A method of fabricating a multilayer retaining ring for a CMP carrier head the method comprising
machining a metal upper portion;
machining a lower plastic portion from a material selected from the group consisting of polyphenylene sulfide (PPS), polyethylene terephthalate, polyetheretherketone, polybutylene terephthalate, Ertalyte TX, PEEK, Torlon, Delrin, PET, Vespel, or Duratrol;
roughening the mating surfaces of the metal and plastic portions;
cleaning the mating surfaces;
applying a acrylic adhesive to at least one of the mating surfaces;
pressing the mating surfaces together to forces a portion of the adhesive to flow out of the ring; and
allowing the adhesive to cure at room temperature without special clamping or fixturing.

9. The method of claim 8 wherein the acrylic adhesive is Loctite Product 324.

10. The method of claim 8 wherein the acrylic adhesive is Loctite Product 325.
